(19) United States
(12) Patent Application Publication
(10) Pub. No.: US 2026/0047238 A1
(43) Pub. Date: Feb. 12, 2026

(54) SEMICONDUCTOR STRUCTURE AND METHOD FOR FORMING THE SAME

(71) Applicant: JADE BIRD DISPLAY (SHANGHAI) LIMITED, Shanghai (CN)

(72) Inventors: Feng FENG, Shanghai (CN); Hao WANG, Shanghai (CN); Jian GUO, Shanghai (CN)

(73) Assignee: JADE BIRD DISPLAY (SHANGHAI) LIMITED, Shanghai (CN)

(21) Appl. No.: 19/294,300

(22) Filed: Aug. 8, 2025

(30) Foreign Application Priority Data
Aug. 8, 2024 (CN) 202411090579.5

(51) Int. Cl. H10H 20/821; H01L 25/16; H10H 20/01; H10H 20/831; H10H 20/856; H10H 20/857

(52) U.S. Cl. CPC H10H 20/821; H01L 25/167; H10H 20/016; H10H 20/018; H10H 20/032; H10H 20/0364; H10H 20/8312; H10H 20/856; H10H 20/857

(57) ABSTRACT

A semiconductor structure and a method for forming the semiconductor structure are provided. The method includes: forming a base including multiple light-emitting mesa regions; forming light-emitting mesas on the base, and the light-emitting mesas being disposed in an array and formed in the multiple light-emitting mesa regions; forming a first bonding layer containing first conductive pillars, and at least a part of the first conductive pillars being disposed on top surfaces of the light-emitting mesas; forming a driver backplane including a second bonding layer, and the second bonding layer containing second conductive pillars corresponding to the at least a part of the first conductive pillars; and detachably bonding the first bonding layer and the second bonding layer, and the at least a part of the first conductive pillars are electrically connected with a part of or all of the second conductive pillars in a one-to-one correspondence.

### FIELD

The present disclosure generally relates to the field of semiconductor manufacturing, and more particularly, to a semiconductor structure and a method for forming the semiconductor structure.

### BACKGROUND

Micro Light Emitting Diode (LED) devices, as light-emitting semiconductor components with miniature size (e.g., less than 50 μm), offer advantages including low power consumption, long lifespan, high brightness, and high contrast ratio. With the gradual advancement of display technology, light-emitting mesa technology has gradually become a trend in next-generation displays and has attracted significant attention.

However, the manufacturing cost of current light-emitting mesa devices remain prohibitively high.

### SUMMARY

Embodiments of the present disclosure provide a semiconductor structure and a method for forming the semiconductor structure, which can reduce the process cost and improve the accurate driving of a light-emitting mesa device by a driver backplane.

Embodiments of the present disclosure provide a method for forming a semiconductor structure. The method includes: forming a base including multiple light-emitting mesa regions; forming light-emitting mesas on the base, and the light-emitting mesas being formed in the multiple light-emitting mesa regions and arranged in an array; forming a first bonding layer containing multiple first conductive pillars, and at least a part of the multiple first conductive pillars being disposed on top surfaces of the light-emitting mesas; forming a driver backplane including a second bonding layer, and the second bonding layer containing multiple second conductive pillars corresponding to the at least a part of the multiple first conductive pillars; and detachably bonding the first bonding layer and the second bonding layer, and the at least a part of the multiple first conductive pillars are electrically connected with a part of or all of the multiple second conductive pillars in a one-to-one correspondence.

According to some embodiments, the method further includes: after detachably bonding the first bonding layer and the second bonding layer, performing an annealing treatment on the driver backplane and the base.

According to some embodiments, performing the annealing treatment on the driver backplane and the base includes: performing a multi-staged temperature-rising process on the driver backplane and the base. The temperature increases from stage to stage, and the heating duration increases from stage to stage.

According to some embodiments, performing the multi-staged temperature-rising process on the driver backplane and the base includes: raising the temperature to a first temperature and maintaining at the first temperature for a first duration; raising the temperature to a second temperature and maintaining at the second temperature for a second duration; and raising the temperature to a third temperature and maintaining at the third temperature for a third duration. The second temperature is higher than the first temperature, and the second duration is longer than the first duration. The third temperature is higher than the second temperature, and the third duration is longer than the second duration.

According to some embodiments, the second duration is twice the first duration, and the third duration is twice the second duration.

According to some embodiments, at least one of the following is satisfied: the first temperature ranging from 80° C. to 120° C.; the second temperature ranging from 180° C. to 220° C.; the third temperature ranging from 220° C. to 350° C.; the first duration ranging from 0.8 h to 1.2 h; the second duration ranging from 1.8 h to 2.2 h; and the third duration ranging from 3.8 h to 4.2 h.

According to some embodiments, first pry holes are disposed at an edge of the base, second pry holes are disposed at an edge of the driver backplane, the first pry holes and the second pry holes are arranged in a one-to-one correspondence. The method may further include: when separation of the driver backplane and the base is required, inserting a separation tool into the first pry holes and/or the second pry holes to pry the driver backplane and/or the base from an interface between the driver backplane and the base, thereby separating the driver backplane and the base.

According to some embodiments, the base contains positioning holes; and a first pry hole and a second pry hole are arranged in pairs, and each pair of pry holes does not overlap with the positioning holes.

According to some embodiments, the light-emitting mesas are formed on a first side of the base, the base further includes first electrode regions, and a part of the multiple first conductive pillars are disposed in the first electrode regions of the base. The method further includes: after detachably bonding the first bonding layer and the second bonding layer, removing a substrate disposed on the base from a second side of the base to expose a back side of the light emitting mesa, and the first side and the second side of the base being opposite to each other; and forming second electrodes and first electrodes on the second side of the base, the first electrodes being disposed in the first electrode regions, and each of the first electrodes being electrically connected with one of the part of the multiple first conductive pillars disposed in the first electrode regions of the base.

According to some embodiments, each of the light-emitting mesas is surrounded by the second electrodes, and the back side of each of the light-emitting mesas is exposed. On a second side of the base, a height of a second electrode is preset times greater than a height of the first electrode.

According to some embodiments, the preset times range from 2 to 10.

According to some embodiments, detachably bonding the first bonding layer and the second bonding layer includes: performing a flip-chip bonding between the first bonding layer and the second bonding layer using van der Waals forces.

Some embodiments of the present disclosure also provide a semiconductor structure. The semiconductor structure includes: a base including multiple light-emitting mesa regions; light-emitting mesas formed in the multiple light-emitting mesa regions and disposed in an array on the base; a first bonding layer containing multiple first conductive pillars, and at least a part of the multiple first conductive pillars being disposed on top surfaces of the light-emitting mesas; and a driver backplane including a second bonding layer, and the second bonding layer containing multiple second conductive pillars corresponding to the at least a part of the multiple first conductive pillars. The first bonding layer and the second bonding layer are detachably bonded, and the at least a part of the multiple first conductive pillars are electrically connected with a part of or all of the multiple second conductive pillars in a one-to-one correspondence.

According to some embodiments, multiple first pry holes are disposed at an edge of the base, multiple second pry holes are disposed at an edge of the driver backplane, and the first pry holes and the second pry holes are arranged in a one-to-one correspondence. The driver backplane can be separated from the base through the first pry holes and/or the second pry holes.

According to some embodiments, the base contains multiple positioning holes; and a first pry hole and a second pry hole are arranged in pairs and each pair of pry holes does not overlap with the positioning holes.

According to some embodiments, the base further includes multiple first electrode regions, and a part of the multiple first conductive pillars are disposed in the multiple first electrode regions of the base. The semiconductor structure further includes: second electrodes, and first electrodes disposed in the first electrode regions. Each of the first electrodes is electrically connected with one of part of the multiple first conductive pillars disposed in the first electrode regions of the base. The second electrodes and the first electrodes are formed on a second side of the base. A back side of the light-emitting mesa is exposed from the second side of the base. The second side of the base is opposite to a first side of the base. The light-emitting mesas are disposed on the first side of the base.

According to some embodiments, each of the light-emitting mesas is surrounded by the second electrodes, and the back side of each of the light-emitting mesas is exposed. On a second side of the base, a height of a second electrode is preset times greater than a height of the first electrode.

According to some embodiments, the preset times range from 2 to 10.

According to some embodiments, the height of the first electrode ranges from 1 nm to 50 mm; and/or the height of the second electrode ranges from 10 nm to 100 mm.

According to some embodiments, the semiconductor structure further includes a light reflection layer covering at least a part of a sidewall of the light emitting mesa.

According to some embodiments, the semiconductor structure further includes a protective layer at least covering the light reflection layer.

Compared with conventional technology, embodiments of the present disclosure have following advantages.

In embodiments of the present disclosure, since the first bonding layer and the second bonding layer are detachably bonded, the base and the driver backplane may be disassembled and reassembled when failure occurs, and the process cost can thus be effectively reduced under the fact that the base and the driver backplane are of high process cost. Further, by forming the first conductive pillar on the top surface of the light-emitting mesa, and by forming the second conductive pillar corresponding to the first conductive pillar in the driver backplane, the detachable bonding connection accuracy between the light-emitting mesa and the driver backplane can be further improved, thereby improving the precise driving of the light-emitting mesa device by the driver backplane.

Further, after the first bonding layer and the second bonding layer are detachably bonded, the driver backplane and the base are annealed to release the gas inside of and between the first bonding layer and the second bonding layer, thereby strengthening the bonding force. Moreover, since the temperature in the annealing process is high, the first conductive pillar and the second conductive pillar are appropriately expanded and melted, thereby further reducing the resistivity between the first conductive pillar and the second conductive pillar.

Further, in the multi-staged temperature-rising process, the temperature increases successively from stage to stage, and the heating duration increases successively from stage to stage. Compared with the rapid annealing process including rapidly raising the temperature to a high temperature and then rapidly cooling down, the gases inside of and between the first bonding layer and the second bonding layer can be gradually released in the multi-staged temperature-rising process of the annealing process in embodiments of the present disclosure, thereby improving the bonding force and also strengthening the melting between the first conductive pillar and the second conductive pillar, which is conducive to further reducing the resistivity between the first conductive pillar and the second conductive pillar.

Further, the second duration is twice the first duration, and the third duration is twice the second duration. In the multi-staged temperature-rising process, a heating duration of a high-temperature stage is longer than that of a low-temperature stage, to further enhance the release effect of the gases inside of and between the first bonding layer and the second bonding layer, and the first conductive pillar and the second conductive pillar can be kept in a molten state for a longer time.

Further, the first pry holes disposed at the edge of the base and the second pry holes disposed at the edge of the driver backplane are arranged in a one-to-one correspondence. When it is necessary to separate the driver backplane from the base, a separation tool may be inserted into the first pry holes and/or the second pry holes to pry the driver backplane and/or the base from the interface between the driver backplane and the base, thereby separating the driver backplane and the base. In light of above, it is possible to detach the base and the driver backplane. Since the disassembly is performed through first holes and/or the second pry holes disposed at the edges, it does not affect the circuit structures in the light-emitting mesa device and the driver backplane, thereby effectively improving the reusability rate of the base and driver backplane and reducing the manufacturing cost.

Further, the base contains positioning holes, the first pry hole and the second pry hole are arranged in pairs, and each pair of pry holes does not overlap with the positioning holes. Therefore, damages to the positioning holes during disassembly via the first pry holes and/or the second pry holes can be effectively avoided, thereby maintaining the positioning alignment accuracy of the light-emitting mesa device while reducing manufacturing cost.

Further, the second electrodes and the first electrodes are formed on the second side of the base, and the first electrodes are disposed in the first electrode regions and electrically connected with the first conductive pillars disposed in the first electrode regions, thereby avoiding the influence of the detachable structure on the second electrodes and the first electrodes, and maintaining the stability of the electrode performance of the original light-emitting mesa device.

Further, on the second side of the base, the height of the second electrode is greater than the height of the first electrode by preset times. By setting the second electrode to be higher than the first electrode, the light path can be effectively restricted, the light-emitting efficiency of the device can be further improved, and crosstalk between pixels can be reduced.

### BRIEF DESCRIPTION OF THE DRAWINGS

FIG. 1 schematically illustrates a flowchart of a method for forming a semiconductor structure according to some embodiments of the present disclosure;

FIG. 2 schematically illustrates a top view of a semiconductor structure according to some embodiments of the present disclosure;

FIG. 3 to FIG. 8 schematically illustrate sectional structural diagrams of devices corresponding to each step in a method for forming a semiconductor structure according to some embodiments of the present disclosure; and

FIG. 9 schematically illustrates a diagram of first pry holes and second pry holes of a semiconductor structure according to some embodiments of the present disclosure.

Reference numerals are illustrated as follows.

Substrate 100, buffer layer 101, epitaxial layer 102, light-emitting mesa 103, transparent conductive layer 104, passivation layer 105, first bonding layer 106, first conductive pillar 107, driver backplane 200, conductive connection structure 201, second bonding layer 206, second conductive pillar 207, N-type electrode 301, P-type electrode 302, microlens 303, light reflection layer 311, and protective layer 312.

### DETAILED DESCRIPTION

As mentioned above, light-emitting mesa device technology is gaining increasing attention. However, the manufacturing cost of current light-emitting mesa devices remain excessively high.

It has been found that a base including light-emitting mesas and a driver backplane including circuit devices are necessary to realize optical properties and electrical properties of a light-emitting mesa device. For example, the base can be formed on the driver backplane including the circuit devices, and the light-emitting mesas can be formed on the base.

However, in existing technology, due to the high process cost of both the base and the driver backplane, scrapped wafer caused by failure will results in excessively high manufacturing cost.

In embodiments of the present disclosure, since the first bonding layer and the second bonding layer are detachably bonded, the base and the driver backplane may be disassembled and reassembled when failure occurs, and the process cost can thus be effectively reduced under the fact that the base and the driver backplane are of high process cost. Further, by forming at least a part of the first conductive pillars on the top surfaces of the light-emitting mesas and in the first electrode regions of the base, and forming the second conductive pillars corresponding to the at least a part of the first conductive pillars in the driver backplane, the detachable bonding connection accuracy between the light-emitting mesa and the driver backplane can be further improved, thereby improving the precise driving of the light-emitting mesa device by the driver backplane.

In order to clarify the object, features, and advantages of embodiments of the present disclosure, embodiments of present disclosure will be described clearly in detail in conjunction with accompanying figures.

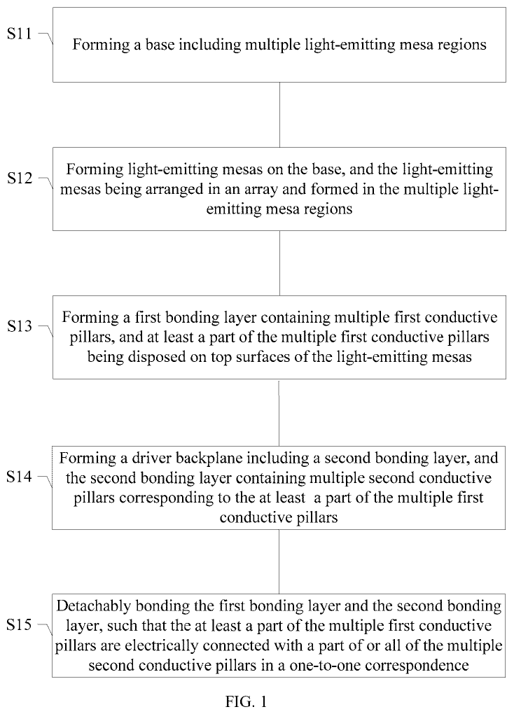

FIG. 1 schematically illustrates a flowchart of a method for forming a semiconductor structure according to some embodiments of the present disclosure. Referring to FIG. 1, the method may include:
step S11: forming a base including multiple light-emitting mesa regions;
step S12: forming light-emitting mesas on the base, and the light-emitting mesas being disposed in an array and formed in the multiple light-emitting mesa regions;
step S13: forming a first bonding layer containing multiple first conductive pillars, and at least a part of the multiple first conductive pillars being disposed on top surfaces of the light-emitting mesas;
step S14: forming a driver backplane including a second bonding layer, and the second bonding layer containing multiple second conductive pillars corresponding to the at least a part of the multiple first conductive pillars;
step S15: detachably bonding the first bonding layer and the second bonding layer, and the at least a part of the multiple first conductive pillars are electrically connected with a part of or all of the multiple second conductive pillars in a one-to-one correspondence.

Each of aforementioned steps is described below in conjunction with the accompanying features.

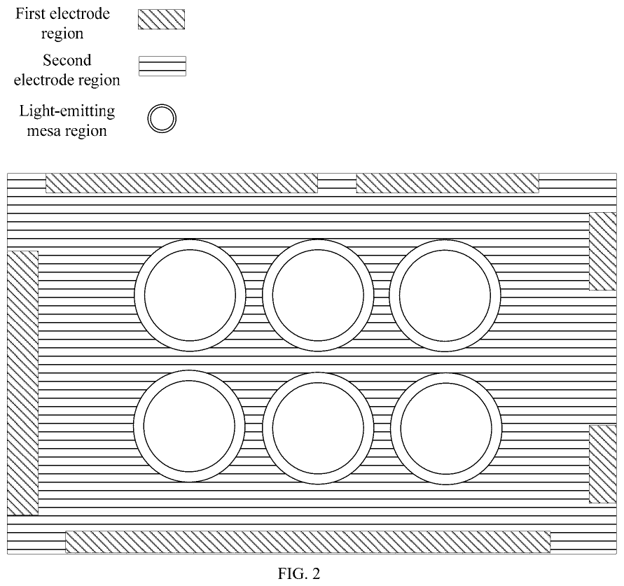

FIG. 2 schematically illustrates a top view of a semiconductor structure according to some embodiments of the present disclosure.

Referring to FIG. 2, the semiconductor structure may include a base, and the base may include multiple light-emitting mesa regions, a second electrode region, and first electrode regions.

Second electrodes may be formed in the second electrode region, and first electrodes may be formed in the first electrode regions.

In the semiconductor structure illustrated in FIG. 2, the second electrode region may be partially surrounded by the first electrode regions.

It should be noted that the semiconductor structure in specific applications is not limited by FIG. 2. For example, the size, number, and position of the first electrode regions may be adjusted according to the specific circumstances.

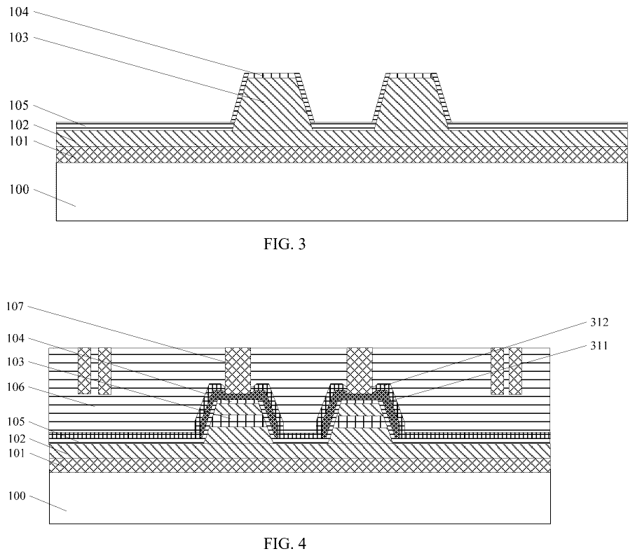

FIG. 3 to FIG. 8 schematically illustrate sectional structural diagrams of devices corresponding to each step in a method for forming a semiconductor structure according to some embodiments of the present disclosure.

Referring to FIG. 3, a base is formed.

Specifically, a substrate 100 may be provided, a buffer layer 101 may be formed on the substrate 100, and an epitaxial layer 102 may be formed on the buffer layer 101.

According to some embodiments, the substrate 100 may include a sapphire substrate and the like, and the composition of the substrate 100 may include aluminum oxide (Al₂O₃).

According to some embodiments, the substrate 100 may include a substrate made of other suitable materials, such as a semiconductor substrate or a silicon substrate. The semiconductor substrate may also be made of a material including germanium, silicon germanium, silicon carbide, gallium arsenide, or indium gallium. The semiconductor substrate may also be a silicon substrate on an insulator or a germanium substrate on an insulator, or be a substrate on which an epitaxial layer is formed.

According to some embodiments, the epitaxial layer 102 may include one or more of the following: a first confinement layer, a quantum well layer, and a second confinement layer.

The first confinement layer may be an N-type III-V compound layer, and correspondingly, the second confinement layer may be a P-type III-V compound layer.

The quantum well layer may include a material suitable for forming a quantum well structure. For example, the quantum well layer may be a III-V compound layer.

It should be noted that the III-V compound layer may represent a material layer made of compound(s) including a Group III element and a Group V element. The Group III element may include B, Al, Ga, and In. The Group V element may include N, P, As, and Sb.

According to some embodiments, the material of the III-V compound layer may be selected according to specific needs, and the specific III-V compounds in the first confinement layer, in the quantum well layer, and in the second confinement layer may be consistent or different.

According to some embodiments, the III-V compound layer may include GaN, GaAs, and InP.

It should be noted that the epitaxial layer 102 may also include other suitable layers, such as a sacrificial layer. Embodiments of the present disclosure does not limit the specific structure of the epitaxial layer 102.

According to some embodiments, a transparent conductive layer 104 may also be formed on the epitaxial layer 102.

The material of the transparent conductive layer 104 may include indium tin oxide (In₂O₅Sn) which may improve electrical conductivity and light extraction effect, and reduce the ohmic effect.

It should be noted that the material of the transparent conductive layer 104 may also include other suitable materials, such as fluorine doped tin oxide (FTO), and zinc oxide (ZnO).

The light emitting mesas 103 may be formed based on the epitaxial layer 102.

Specifically, the light-emitting mesas 103 may be formed by etching the transparent conductive layer 104 and the epitaxial layer 102 through a photolithography process and an etching process. Other appropriate process may also be used, and embodiments of the present disclosure impose no limitations on the specific process for forming the light-emitting mesas 103.

It should be noted that a part of the first confinement layer in the epitaxial layer 102 may be retained during the process for forming the light-emitting mesas 103.

According to some embodiments, a passivation layer 105 may also be formed to cover the base, and the top surface of the light-emitting mesa 103 is exposed from the passivation layer 105. In other words, the passivation layer 105 may cover a sidewall of the light-emitting mesa 103.

In a process for forming the passivation layer 105, the material of the passivation layer can first be formed to cover the transparent conductive layer 104, and then the material of the passivation layer disposed on the top surface of each light-emitting mesa 103 can be removed.

According to some embodiments, the material of the passivation layer 105 may include one or more selected from a group consisting of silicon oxide, aluminum oxide, silicon nitride, and polyimide.

Specifically, the material of the passivation layer can be removed through photolithography, etching processes, or other suitable processes. Embodiments of the present disclosure are not limited by specific processes.

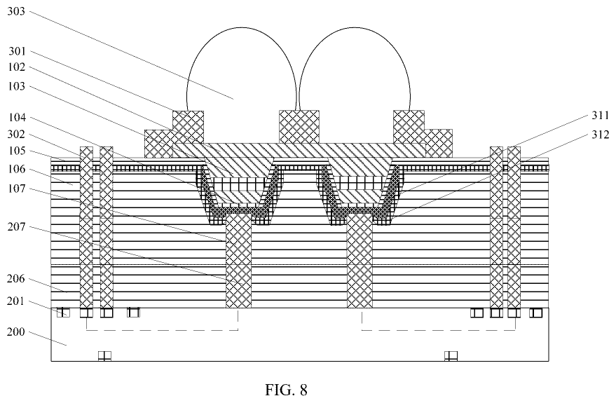

According to an embodiment, a light reflection layer (e.g., the light reflection layer 311 shown in FIG. 8,) may also be formed on the passivation layer 105 and transparent conductive layer 104 disposed on the light-emitting mesa 103, and the path of the light emitted from the quantum well layer can be changed through reflection by the light reflection layer, and the light extraction efficiency of the semiconductor structure can be effectively improved.

Referring to FIG. 4, a first bonding layer 106 is formed on the base, and multiple first conductive pillars 107 are formed in the first bonding layer 106.

A part of the multiple first conductive pillars 107 may be disposed on the top surfaces of the light-emitting mesas 103, and a part of the multiple first conductive pillars 107 may be disposed in the first electrode regions of the base. Specifically, a material layer of the first bonding layer 106 may be formed first, and then the first bonding layer 106 may be etched to form through holes (not shown in the figures). The top surface of the light-emitting mesas 103 and the first electrode regions are exposed from the through holes in the first bonding layer 106, and then the first conductive pillars 107 may be formed in the through holes.

According to an embodiment, a part of the multiple first conductive pillars 107 are disposed on the top surfaces of the light-emitting mesas 103 in a one-to-one correspondence. Specifically, each of the part of the multiple first conductive pillars 107 is disposed on one of the top surface of the light-emitting mesas 103.

According to an embodiment, the material of the first bonding layer 106 may include one or more selected from a group consisting of silicon oxide, aluminum oxide, and silicon nitride.

The material of the first conductive pillar 107 may include one or more selected from a group consisting of copper, tungsten, aluminum, silver, platinum, and gold.

According to an embodiment, a light reflection layer may be formed on the passivation layer 105 and the transparent conductive layer 104 disposed on the light-emitting mesa 103. Therefore, the light reflection layer disposed on the top surface of the light-emitting mesa 103 can be exposed from the through holes.

It is understandable that the depth of one of the first conductive pillars 107 disposed on the top surface of the light-emitting mesa 103 may be consistent with the depth of one of the first conductive pillars 107 disposed in the first electrode regions.

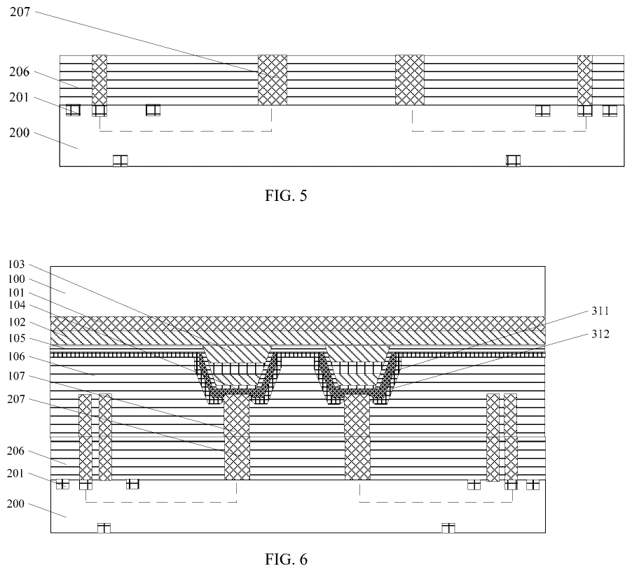

Referring to FIG. 5, a driver backplane 200 is formed, a second bonding layer 206 is formed on the driver backplane 200, and second conductive pillars 207 are formed in the second bonding layer 206.

The second conductive pillars 207 may be arranged in one-to-one positional correspondence with the first conductive pillars 107.

The driver backplane 200 may be a Thin Film Transistor (TFT) board or an Integrated Circuit (IC) board.

The driver backplane 200 may include conductive connection structures 201, such as a conductive interconnect layer including conductive wires and conductive plugs.

According to an embodiment, the material of the second bonding layer 206 may include one or more selected from a group consisting of silicon oxide and silicon nitride.

The material of the second conductive pillar 207 may include one or more selected from a group consisting of copper, tungsten, aluminum, silver, platinum, and gold.

Referring to FIG. 6, the first bonding layer 106 and the second bonding layer 206 are detachably bonded, and the at least a part of the first conductive pillars 107 are electrically connected with a part of or all of the second conductive pillars 207 in a one-to-one correspondence. According to some embodiments, the first bonding layer 106 and the second bonding layer 206 may be flip-chip bonded through van der Waals forces, and the first conductive pillar 107 and the second conductive pillar 207 are electrically connected in a one-to-one correspondence.

Specifically, the light-emitting mesas 103 and the first conductive pillars 107 are formed on the first side of the base, the substrate 100 is disposed on the second side of the base, and the first side and second side of the base are opposite to each other. The second conductive pillars 207 are formed on a first side of the driver backplane 200.

The driver backplane 200 may be flip-chip bonded to the base by bonding the first side of the base to the first side of the driver backplane 200.

Van der Waals forces, also known as intermolecular force or weak intermolecular interaction, are forces that exist only between molecules or between atoms of noble gases, and exhibit additivity and are classified as a secondary bond.

Specifically, atoms or molecules with originally stable atomic structures can be combined into a unified entity by bonding through the weak and instantaneous induced interactions of electric dipole moments of van der Waals forces, resulting in high robustness and convenient detachability.

In embodiments of the present disclosure, a detachable bonding connection can be formed between the driver backplate 200 and the base by detachably bonding the first bonding layer 106 and the second bonding layer 206. The base and the driver backplane may be disassembled and reassembled when failure occurs, and the process cost can thus be effectively reduced under the fact that the base and the driver backplane are of high process cost. Further, by forming the first conductive pillar 107 on the top surface of the light-emitting mesa 103, and by forming the second conductive pillar 207 corresponding to the first conductive pillar 107 in the driver backplane 200, the detachable bonding connection accuracy between the light-emitting mesa 103 and the driver backplane 200 can be further improved, thereby improving the precise driving of the light-emitting mesa device by the driver backplane 200.

Further, the method shown in FIG. 1 may also include performing an annealing treatment on the driver backplane 200 and the base.

It should be noted that gases are likely to appear inside of and between the first bonding layer 106 and the second bonding layer 206 after detachable bonding, especially when the first bonding layer 106 and the second bonding layer 206 are bonded through van der Waals forces, it is easier to separate the first bonding layer 106 and the second bonding layer 206 due to gases at the bonding interface.

In some embodiments of the present disclosure, after the driver backplane 200 and the base are flip-chip bonded through van der Waals forces, the gases inside of and between the first bonding layer 106 and the second bonding layer 206 are released through an annealing treatment on the driver backplane 200 and the base, thereby strengthening the bonding force. Moreover, since the temperature in the annealing process is high, the first conductive pillar 107 and the second conductive pillar 207 are appropriately expanded and melted, thereby further reducing the resistivity between the first conductive pillar 107 and the second conductive pillar 207.

Further, performing the annealing treatment on the driver backplane 200 and the base may include steps: performing a multi-staged temperature-rising process on the driver backplane 200 and the base, and the temperature increases from stage to stage, and the heating duration increases from stage to stage.

In some embodiments of the present disclosure, in the multi-staged temperature-rising process, the temperature increases successively from stage to stage, and the heating duration increases successively from stage to stage. Compared with the rapid annealing process including rapidly raising the temperature to a high temperature and then rapidly cooling down, the gases inside of and between the first bonding layer 106 and the second bonding layer 206 can be gradually released in the multi-staged temperature-rising process of the annealing process in embodiments of the present disclosure, thereby improving the bonding force and also strengthening the melting between the first conductive pillar 107 and the second conductive pillar 207, which is conducive to further reducing the resistivity between the first conductive pillar 107 and the second conductive pillar 207.

According to some embodiments, performing the multi-staged temperature-rising process on the driver backplane and the base may include steps: raising the temperature to a first temperature and maintaining at the first temperature for a first duration, raising the temperature to a second temperature and maintaining at the second temperature for a second duration, and raising the temperature to a third temperature and maintaining at the third temperature for a third duration. The second temperature is higher than the first temperature, and the second duration is longer than the first duration. The third temperature is higher than the second temperature, and the third duration is longer than the second duration.

Specifically, the first temperature T1, the second temperature T2, and the third temperature T3 may be set to satisfy T1<T2<T3. The first duration Time1, the second duration Time2, and the third duration Time3 may be set to satisfy Time1<Time2<Time3.

It should be noted that, depending on specific requirements, the multi-staged temperature-rising process may include fewer than three stages or more than three stages.

According to some embodiments, performing the multi-staged temperature-rising process on the driver backplane and the base may include steps: raising the temperature to a first temperature and maintaining at the first temperature for a first duration, and raising the temperature to a second temperature and maintaining at the second temperature for a second duration. The second temperature is higher than the first temperature, and the second duration is longer than the first duration.

Specifically, the first temperature T1 and the second temperature T2 may be set to satisfy T1<T2, and the first duration Time1 and the second duration Time2 may be set to satisfy Time1<Time2. Further, the second duration can be twice the first duration, and the third duration can be twice the second duration.

Specifically, it may be T2=2T1, and T3=2T2.

In some embodiments of the present disclosure, the second duration is twice the first duration, and the third duration is twice the second duration. In the multi-staged temperature-rising process, a heating duration of a high-temperature stage can be longer than that of a low-temperature stage, which can enhance the release effect of the gases inside of and between the first bonding layer 106 and the second bonding layer 206, and the first conductive pillar 107 and the second conductive pillar 207 can be kept in a molten state for a longer time.

According to some embodiments, one or more of the following may be satisfied:
the first temperature ranges from 80° C. to 120° C., for example, it may be 100° C.;
the second temperature ranges from 180° C. to 220° C., for example, it may be 200° C.;
the third temperature ranges from 220° C. to 350° C., for example, it may be 250° C.;
the first duration ranges from 0.8 h to 1.2 h, for example, it may be 1 h;
the second duration ranges from 1.8 h to 2.2 h, for example, it may be 2 h; and
the third duration ranges from 3.8 h to 4.2 h, for example, it may be 4 h.

In an embodiment, the temperature can be heated to 100° C. and maintained at 100° C. for 1 hour in the first stage; the temperature can be heated to 200° C. and maintained at 200° C. for 2 hours in the second stage; and the temperature can be heated to 250° C. and maintained at 250° C. for 4 hours in the third stage.

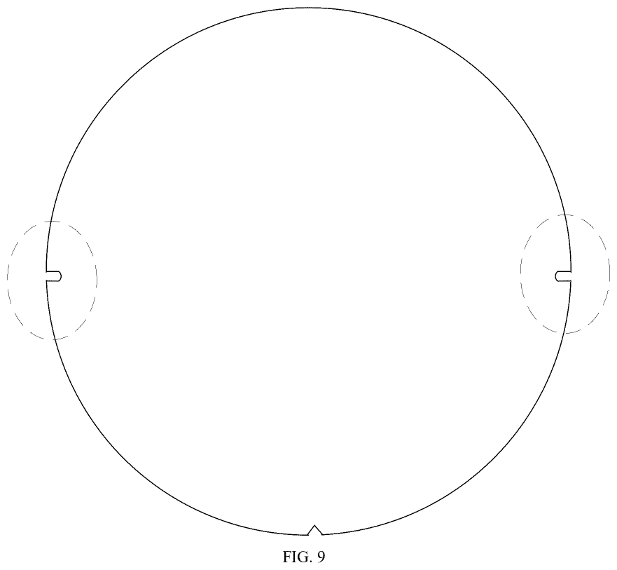

FIG. 9 schematically illustrates a diagram of first pry holes and second pry holes of a semiconductor structure according to some embodiments of the present disclosure.

As shown by the dashed ellipse in FIG. 9, first pry holes are disposed at an edge of the base, and second pry holes are disposed at an edge of the driver backplane, the first pry holes and the second pry holes are arranged in a one-to-one correspondence. The driver backplane may be separated from the base through the first pry holes and/or the second pry holes.

According to some embodiments of the present disclosure, the first pry holes disposed at the edge of the base and the second pry holes disposed at the edge of the driver backplane are in a one-to-one correspondence, and the driver backplane may be separated from the base through the first pry holes and/or the second pry holes. The base and the driver backplane can be effectively disassembled through the first pry holes and/or second pry holes disposed at the edge, which does not affect the circuit structures in the light-emitting mesa device and the driver backplane. Therefore, the reusability rate of the base and the driver backplane can be effectively improved and the manufacturing cost can be reduced.

Further, the base may contain positioning holes. A first pry hole and a second pry hole may be arranged in pairs, and each pair of pry holes does not overlap with the positioning holes.

According to some embodiments of the present disclosure, the base contains positioning holes, a first pry hole and a second pry hole are arranged in pairs, and each pair of pry holes does not overlap with the positioning holes. Therefore, damages to the positioning holes during disassembly via the first pry holes and/or the second pry holes can be effectively avoided, thereby maintaining the positioning alignment accuracy of the light-emitting mesa device while reducing manufacturing cost.

Referring to FIG. 6, the light-emitting mesa 103 may be formed on the first side of the base, and the semiconductor structure may be processed from a second side of the base in subsequent processes.

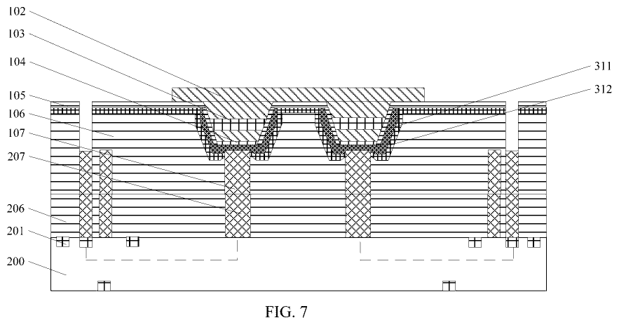

Referring to FIG. 7, the substrate 100 and the buffer layer 101 disposed on a surface of the base may be removed from the second side of the base to expose a back surface of the light-emitting mesa 103, and the first electrode regions may be etched to form grooves or holes for forming the first electrodes.

According to some embodiments, the first side and the second side of the base are opposite to each other, and the grooves or holes for forming the first electrodes correspond one-to-one with the first conductive pillars 107 in the first electrode regions.

During the aforementioned process for forming the light-emitting mesa 103, a portion of the thickness of the first confinement layer may be left behind. Therefore, the retained first confinement layer may be exposed from the exposed back surface of the light-emitting mesa 103.

According some embodiments, a portion of the epitaxial layer 102 disposed on the passivation layer 105 may be removed, and the epitaxial layer 102 in the light emitting mesa region may be retained.

It should be noted that the first electrode may be one of an N-type electrode and a P-type electrode, and the second electrode is the other of the N-type electrode and the P-type electrode.

In the following text and the accompanying figures, in order to avoid misunderstanding caused by vague description, the P-type electrode serves as the first electrode, and the N-type electrode serves as the second electrode.

However, it should be noted that the specific embodiment is not limited thereto. For example, an N-type electrode serves as the first electrode, and a P-type electrode serves as the second electrode.

Referring to FIG. 8, N-type electrodes 301 are formed on the second side of the base, and P-type electrodes 302 are formed in the first electrode regions. Each of the P-type electrodes 302 is electrically connected with one of the first conductive pillars 107 disposed in the first electrode regions.

According some embodiments, microlenses 303 may also be formed.

Specifically, the materials of the N-type electrode 301 and the P-type electrode 302 can be conventional electrode materials, such as conductive materials, for example, suitable metal materials including copper, aluminum, platinum, silver, gold, various conductive compound materials, and the like.

The material of the microlenses 303 may be a conventional lens material, such as a material with a light transmittance greater than a preset light transmittance threshold.

According some embodiments of the present disclosure, the N-type electrode 301 is formed on the second side of the base, and a P-type electrode 302 electrically connected with the first conductive pillar 107 is formed in the first electrode region. Therefore, the influence of the detachable structure on the N-type electrode 301 and the P-type electrode 302 can be avoided, and the stability of the electrode performance of the original light-emitting mesa device can be maintained.

It should be particularly pointed out that, in embodiments as shown in FIG. 4 to FIG. 8, the semiconductor structure may further include a light reflection layer 311 and a protective layer 312.

The light reflection layer 311 may be formed on a part of or the entire sidewall surface of the light emitting mesa.

Specifically, since the light reflection layer 311 is formed on a part of or the entire sidewall surface of the light-emitting mesa 103, the light emitted by the light-emitting mesa 103 can be effectively reflected. As a result, a part of the light emitted by the light-emitting mesa 103 that is not included in the preset light-emitting angle (e.g., an angle within plus or minus 20 degrees) can be reflected by the light reflection layer 311, thereby changing the light path direction to be within the preset light-emitting angle, and effectively improving the light extraction efficiency and brightness of the micro-LED display chip.

According to some embodiments, the protective layer 312 at least covers the light reflection layer 311.

In addition, the protective layer 312 may be formed on the base, and the protective layer 312 at least covers the light reflection layer 311. The light reflection layer 311 may be made of a relatively active metal material which is prone to electromigration and metal material diffusion, the protective layer 312 at least covering the light reflection layer 311 can effectively control the electromigration and metal material diffusion, leading to improving the lifespan and light-emitting efficiency of the micro LED display chip.

Further, the light-emitting mesa 103 may be surrounded by the N-type electrodes 301 and the back side of the light-emitting mesa 103 may be exposed. On the second side of the base, the height of the N-type electrode 301 may be greater than the height of the P-type electrode 302 by preset times.

According to some embodiments of the present disclosure, on the second side of the base, the height of the N-type electrode 301 may be greater than the height of the P-type electrode 302 by preset times. Therefore, the light path can be effectively restricted by the N-type electrode 301 which is higher than the P-type electrode 302, the light-emitting efficiency of the device can be further improved, and crosstalk between pixels can be reduced.

Further, the preset times may range from 2 to 10.

According to some embodiments, compared with the height of the P-type electrode 301, the height of the N-type electrode 301 can be set to be double (e.g., 2 times) or an increased order magnitude (e.g., 10 times) to achieve an appropriate height.

Further, the height of the first electrode (e.g., P-type electrode 302) may range from 1 nm to 50 mm; and/or the height of the second electrode (e.g., N-type electrode 301) may range from 10 nm to 100 mm.

According to some embodiments of the present disclosure, the quality of the device can be further improved by setting the height of the P-type electrode 302 and the height of the N-type electrode 301 appropriately.

According to some embodiments, first pry holes are disposed at an edge of the base, second pry holes are disposed at an edge of the driver backplane 200, and the first pry holes and the second pry holes are in a one-to-one correspondence. The method for forming the semiconductor structure further includes: when separating the driver backplane 200 from the base, inserting a separation tool into the first pry holes and/or the second pry holes to pry the driver backplane 200 or the base from an interface between the driver backplane 200 and the base, thereby separating the driver backplane 200 and the base.

The separation tool may be a flat tool that is adapted to the size of the pry hole, such as a pry bar or a pry rod.

It should be noted that the method may further include: after separating the driver backplane 200 from the base, reassembling the driver backplane 200 with a new base, or reassembling the base with a new driver backplane.

Some embodiments of the present disclosure also provide a semiconductor structure. Referring to FIG. 8, the semiconductor structure may include: a base including multiple light-emitting mesa regions; light-emitting mesas 103 arranged in an array and formed in the multiple light-emitting mesa regions, and the light-emitting mesas 103 being disposed on the base; a first bonding layer 106 containing multiple first conductive pillars 107, and at least a part of the multiple first conductive pillars 107 being disposed on top surfaces of the light-emitting mesas 103; and a driver backplane 200 including a second bonding layer 206, and the second bonding layer 206 containing multiple second conductive pillars 207 corresponding to the at least a part of the multiple first conductive pillars 107. The first bonding layer 106 and the second bonding layer 206 are detachably bonded, and the at least a part of the multiple first conductive pillars 107 are electrically connected with a part of or all of the multiple second conductive pillars 207 in a one-to-one correspondence.

According to an embodiment, the at least a part of the multiple first conductive pillars 107 may be disposed on the top surfaces of the light-emitting mesas 103 in a one-to-one correspondence. Specifically, each of the at least a part of the multiple first conductive pillars 107 may be disposed on one of the top surface of the light-emitting mesas 103.

According to some embodiments, first pry holes are disposed at an edges of the base, second pry holes are disposed at an edges of the driver backplane 200, and the first pry holes and the second pry holes are arranged in a one-to-one correspondence, thus the driver backplane 200 can be separated from the base through the first pry holes and/or the second pry holes.

According to some embodiments, the base contains positioning holes; and a first pry hole and a second pry hole are arranged in pairs and each pair of pry holes does not overlap with the positioning holes.

According to some embodiments, the base further includes first electrode regions, and a part of the first conductive pillars are disposed in the first electrode regions of the base. Second electrodes (e.g., N-type electrodes 301) and first electrodes (e.g., P-type electrodes 302) are formed on a second side of the base, and each of the first electrodes is disposed in the first electrode regions and electrically connected with one of the first conductive pillars 107 disposed in the first electrode regions of the base. A back side of the light-emitting mesa 103 is exposed from the second side of the base. The second side of the base is opposite to a first side of the base. Light-emitting mesas 103 are disposed on the first side of the base.

According to some embodiments, the light-emitting mesa 103 is surrounded by the N-type electrodes 301, and the back side of the light-emitting mesa 103 is exposed. On the second side of the base, the height of an N-type electrode 301 is preset times greater than the height of a P-type electrode 302.

According to some embodiments, the preset times range from 2 to 10.

According to some embodiments, the height of the first electrode ranges from 1 nm to 50 mm; and/or the height of the second electrode ranges from 10 nm to 100 mm.

According to some embodiments, the semiconductor structure further includes a light reflection layer 311 covering at least a part of a sidewall of the light emitting mesa 103.

According to some embodiments, the semiconductor structure further includes a protective layer 312 at least covering the light reflection layer 311.

For more details regarding the principles, specific implementation, and beneficial effects of this semiconductor structure, please refer to the aforementioned descriptions of the method for forming the semiconductor structure, which will not be repeated.

It should be noted that, the term “and/or” in this specification describes only an association relationship for describing associated objects and represents that three relationships may exist. For example, A and/or B may represent the following three cases: Only A exists, both A and B exist, and only B exists. In addition, the character “/” generally indicates an “or” relationship between the associated objects. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

In embodiments of the present disclosure, “a plurality of” means two or more than two.

In embodiments of the present disclosure, relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

It should be noted that the sequence numbers of the steps in embodiments do not represent a limitation on the order of execution of the steps.

In the foregoing specification, embodiments have been described with reference to numerous specific details that can vary from implementation to implementation. Certain adaptations and modifications of the described embodiments can be made. Other embodiments can be apparent in the art from consideration of the specification and practice of the disclosure disclosed herein. It is intended that the specification and examples be considered as exemplary only, with a true scope and spirit of the disclosure being indicated by the following claims. It is also intended that the sequence of steps shown in figures are only for illustrative purposes and are not intended to be limited to any particular sequence of steps. As such, these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

Although the present disclosure has been disclosed above with reference to some embodiments thereof, it should be understood that the disclosure is presented by way of example only, and not limitation. Therefore, the protection scope of the present disclosure shall be subject to the scope of the claims.

What is claimed is:

1. A method for forming a semiconductor structure, comprising:
forming a base comprising multiple light-emitting mesa regions;
forming light-emitting mesas on the base, wherein the light-emitting mesas are disposed in an array and formed in the multiple light-emitting mesa regions;
forming a first bonding layer containing multiple first conductive pillars, wherein at least a part of the multiple first conductive pillars are disposed on top surfaces of the light-emitting mesas;
forming a driver backplane comprising a second bonding layer, wherein the second bonding layer contains multiple second conductive pillars corresponding to the at least a part of the multiple first conductive pillars; and
detachably bonding the first bonding layer and the second bonding layer, wherein the at least a part of the multiple first conductive pillars are electrically connected with a part of or all of the multiple second conductive pillars in a one-to-one correspondence.

2. The method according to claim 1, further comprising: after detachably bonding the first bonding layer and the second bonding layer, performing an annealing treatment on the driver backplane and the base.

3. The method according to claim 2, wherein performing the annealing treatment on the driver backplane and the base comprises:
performing a multi-staged temperature-rising process on the driver backplane and the base;
wherein the temperature increases from stage to stage, and the heating duration increases from stage to stage.

4. The method according to claim 3, wherein performing the multi-staged temperature-rising process on the driver backplane and the base comprises:
raising the temperature to a first temperature and maintaining at the first temperature for a first duration;
raising the temperature to a second temperature and maintaining at the second temperature for a second duration, wherein the second temperature is higher than the first temperature, and the second duration is longer than the first duration; and
raising the temperature to a third temperature and maintaining at the third temperature for a third duration, wherein the third temperature is higher than the second temperature, and the third duration is longer than the second duration.

5. The method according to claim 4, wherein the second duration is twice the first duration, and the third duration is twice the second duration.

6. The method according to claim 4, wherein at least one of the following is satisfied:
the first temperature ranging from 80° C. to 120° C.;
the second temperature ranging from 180° C. to 220° C.;
the third temperature ranging from 220° C. to 350° C.;
the first duration ranging from 0.8 h to 1.2 h;
the second duration ranging from 1.8 h to 2.2 h; and
the third duration ranging from 3.8 h to 4.2 h.

7. The method according to claim 1, wherein first pry holes are disposed at an edge of the base, second pry holes are disposed at an edge of the driver backplane, and the first pry holes and the second pry holes are arranged in a one-to-one correspondence; and
the method further comprises: when separation of the driver backplane and the base is required, inserting a separation tool into the first pry holes and/or the second pry holes to pry the driver backplane and/or the base from an interface between the driver backplane and the base, thereby separating the driver backplane from the base.

8. The method according to claim 1, wherein the light-emitting mesas are formed on a first side of the base, the base further comprises first electrode regions, and a part of the multiple first conductive pillars are disposed in the first electrode regions of the base; and
the method further comprises:
after detachably bonding the first bonding layer and the second bonding layer, removing a substrate disposed on the base from a second side of the base, and exposing a back side of the light emitting mesa, wherein the first side and the second side of the base are opposite to each other; and
forming second electrodes and first electrodes on the second side of the base, wherein the first electrodes is disposed in the first electrode regions, and each of the first electrodes is electrically connected with one of the part of the multiple first conductive pillars disposed in the first electrode regions of the base.

9. The method according to claim 8, wherein each of the light-emitting mesas is surrounded by the second electrodes, and the back side of each of the light-emitting mesas is exposed; and
on a second side of the base, a height of a second electrode is preset times greater than a height of the first electrode.

10. The method according to claim 9, wherein the preset times range from 2 to 10.

11. The method according to claim 1, wherein detachably bonding the first bonding layer and the second bonding layer comprises:
performing a flip-chip bonding between the first bonding layer and the second bonding layer using van der Waals forces.

12. A semiconductor structure, comprising:
a base comprising multiple light-emitting mesa regions;
light-emitting mesas disposed in an array and in the multiple light-emitting mesa regions, wherein the light-emitting mesas are disposed on the base;
a first bonding layer containing multiple first conductive pillars, wherein at least a part of the multiple first conductive pillars are disposed on top surfaces of the light-emitting mesas; and
a driver backplane comprising a second bonding layer, wherein the second bonding layer contains multiple second conductive pillars corresponding to the at least a part of the multiple first conductive pillars;
wherein the first bonding layer and the second bonding layer are detachably bonded, and the at least a part of the multiple first conductive pillars are electrically connected with a part of or all of the multiple second conductive pillars in a one-to-one correspondence.

13. The semiconductor structure according to claim 12, wherein first pry holes are disposed at an edge of the base, second pry holes are disposed at an edge of the driver backplane, and the first pry holes and the second pry holes are arranged in a one-to-one correspondence; and
the driver backplane is adapted to be separated from the base through the first pry holes and/or the second pry holes.

14. The semiconductor structure according to claim 13, wherein the base contains positioning holes; and
a first pry hole and a second pry hole are arranged in pairs and each pair of pry holes does not overlap with the positioning holes.

15. The semiconductor structure according to claim 12, wherein the base further comprises first electrode regions, and a part of the multiple first conductive pillars are disposed in the first electrode regions of the base; and
the semiconductor structure further comprises:
second electrodes; and
first electrodes disposed in the first electrode regions, wherein each of the first electrodes is electrically connected with one of the part of the multiple first conductive pillars disposed in the first electrode regions of the base, and the second electrodes and the first electrodes are formed on a second side of the base;
wherein a back side of each of the light-emitting mesas is exposed from the second side of the base; and
the second side of the base is opposite to a first side of the base, and light-emitting mesas are disposed on the first side of the base.

16. The semiconductor structure according to claim 15, wherein each of the light-emitting mesas is surrounded by the second electrodes, and the back side of each of the light-emitting mesas is exposed; and
on a second side of the base, a height of a second electrode is preset times greater than a height of the first electrode.

17. The semiconductor structure according to claim 16, wherein the preset times range from 2 to 10.

18. The semiconductor structure according to claim 17, wherein the height of the first electrode ranges from 1 nm to 50 mm; and/or
the height of the second electrode ranges from 10 nm to 100 mm.

19. The semiconductor structure according to claim 16, further comprising:
a light reflection layer covering at least a part of a sidewall of the light emitting mesa.

20. The semiconductor structure according to claim 19, further comprising:
a protective layer at least covering the light reflection layer.
